(19) United States
(12) Patent Application Publication
(10) Pub. No.: US 2011/0110540 A1
(43) Pub. Date: May 12, 2011

(54) SHELF

(75) Inventor: MARC MISPELKAMP, KREFELD (DE)

(73) Assignee: FINITE ELEMENTE GMBH, BRILON (DE)

(21) Appl. No.: 12/941,564

(22) Filed: Nov. 8, 2010

(30) Foreign Application Priority Data
Nov. 7, 2009 (DE) 10 2009 052 310.3
Feb. 24, 2010 (DE) 10 2010 009 089.1

(51) Int. Cl. H03F 99/00

(52) U.S. Cl. 381/120

(57) ABSTRACT

A shelf is equipped with an audio amplifier and at least one loudspeaker. The shelf can be integrated into the interior design as a shelf while providing multimedia use for audio playback, video output, and connection to a computer, as well as serve for the high-quality enjoyment of music and its functional application, using only one device.

### CROSS-REFERENCE TO RELATED APPLICATION

This application claims the priority, under 35 U.S.C. §119, of German patent applications Nos. DE 10 2009 052 310.3, filed Nov. 7, 2009, and DE 10 2010 009 089.1, filed Feb. 24, 2010; the prior applications are herewith incorporated by reference in their entirety.

### BACKGROUND OF THE INVENTION

### Field of the Invention

The present invention relates to a shelf device.

Shelves as such are sufficiently well known. Typically, they are rectangular plates that can be slotted into a rack or fixed to a wall.

The well-known shelf has a substantially limited functionality, that is, it is provided for having objects, such as books and the like, placed on it.

### SUMMARY OF THE INVENTION

It is an object of the invention to provide a shelf which overcomes a variety of disadvantages of the heretofore-known devices of this general type and which provides for a shelf having enhanced functionality and functions.

With the foregoing and other objects in view there is provided, in accordance with the invention, a shelf, comprising:

a shelf base body; and

an audio amplifier and at least one loudspeaker connected to said audio amplifier mounted to the shelf base body.

In a preferred embodiment, the shelf base body is formed with a plurality of voids. A variety of electronic devices, including an audio amplifier and at least one loudspeaker, are integrated in the shelf base body and disposed in the voids to form an unitary structure. An interface for an audio player is configured to receive signals from the audio player and transmit them to be amplified in the audio amplifier and played over the loudspeaker.

In other words, according to the present invention the shelf is equipped with an audio amplifier and at least one loudspeaker. In this way, the shelf is not just suitable for supporting objects, but is also suitable for playing back audio signals, in particular music and speech. By these means a seemingly “conventional” shelf can be used as a hi-fi system. It can be integrated into the interior design as a shelf while providing multimedia use for audio playback, video output and connection to a computer, whereby, amongst other things, one device can be used for both the high-quality enjoyment of music and its functional application. It goes without saying that the suggested shelf continues to serve its original function, of having objects placed on it.

Further advantageous embodiments of the suggested invention can be derived, in particular, from the features of the dependent claims.

The subject matter of the various claims can be combined in any desired fashion.

In a preferred embodiment, the shelf has the basic form of a rectangular parallelepiped. Of course, other shelf shapes are also conceivable, such as semicircular shapes, etc.

In a further advantageous embodiment of the shelf according to the present invention, the shelf can be equipped with at least one recess for the at least one loudspeaker. The original outward appearance of a “conventional” shelf can be maintained since the required loudspeakers can be recessed in the shelf in a suitable manner.

Furthermore it can be provided in an advantageous manner that at least a first pair of recesses is arranged in the respective bottom surface of the shelf, the first pair of recesses being equipped with bass and/or mid-frequency loudspeakers. Suitably, the comparatively voluminous bass and/or mid-frequency loudspeakers are installed in an area of the shelf that cannot be directly seen by the observer. In this way, the outward appearance of a “conventional shelf” is maintained best possible.

In a further advantageous embodiment of the suggested shelf, it can be provided that at least a second pair of recesses is arranged in the front surface of the shelf, the second pair of recesses being equipped with high-frequency loudspeakers. Suitably, the high-frequency loudspeakers are arranged in an area of the front surface of the shelf and as far apart as possible, i.e. in the end areas of the shelf, to achieve the best possible detection, or the best possible stereo effect.

Furthermore, it can be advantageously provided that the shelf is equipped with connection means for wall mounting. By these means it is not only possible to insert it into a rack but also to mount it freely on a wall.

In an advantageous embodiment of the suggested invention, it can be provided that the shelf is equipped with at least one interface for electronic devices, in particular multimedia devices, preferably audio devices. Suitable interfaces can be used for connection to suitable electronic devices, which provide the audio signal, for example, which is amplified by the audio amplifier and output by means of the at least one loudspeaker.

The interfaces can preferably be an “iPod® Dock” and/or a USB interface and/or an AUX connection and/or a video connection. The at least one interface is not necessarily provided only for supplying signals to the audio amplifier. The video connection can, for example, output a video signal of the inserted iPod to a television set placed on the shelf. The options for configuring the interfaces are ultimately unlimited and can be adapted to future standards.

Furthermore, it can be advantageously provided that the shelf is equipped with a power connection and/or a power supply. Suitably, the shelf is equipped with a separate power connection or power supply so that, for example, at least the audio amplifier can be fed by the above-mentioned power source.

Other features which are considered as characteristic for the invention are set forth in the appended claims.

Although the invention is illustrated and described herein as embodied in a shelf, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is a perspective view of a shelf according to the present invention;

FIG. 2 is a plan view of the shelf according to the present invention;

FIG. 3 is a side view of the shelf according to the present invention;

FIG. 4 is a side view of the shelf according to the present invention;

FIG. 5 is a front view of the shelf according to the present invention; and

FIG. 6 is a bottom view of the shelf according to the present invention.

### DETAILED DESCRIPTION OF THE INVENTION

Referring now to the figures of the drawing in detail, the following is a list of reference numerals that will be used throughout the drawing and the associated description of the figures:
1 base body
2 audio amplifier
3 high-frequency loudspeaker
4 low-frequency/mid-frequency loudspeaker
5 first recesses
6 second recesses
7 interface (e.g., iPod® Dock)
8 top surface
9 bottom surface
10 side surface
11 side surface (front)
12 side surface (back)
13 wall mounting hardware
14 power connector and/or power supply

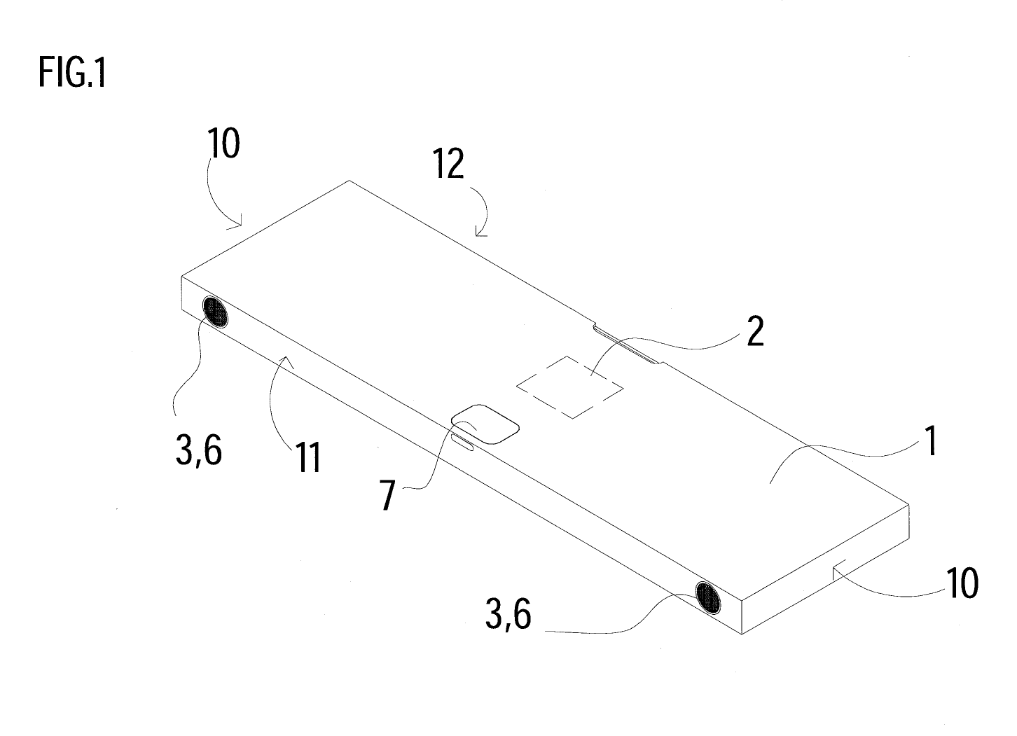

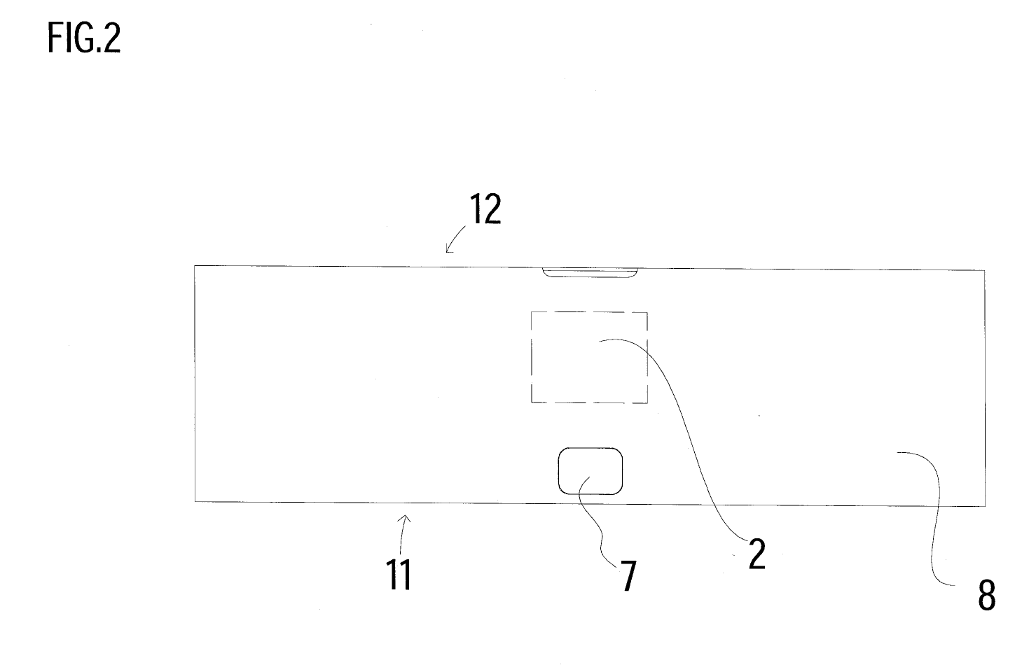

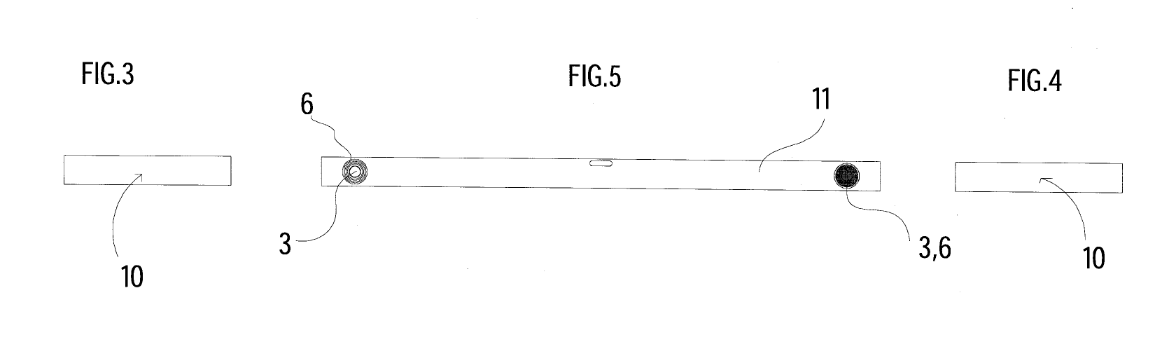

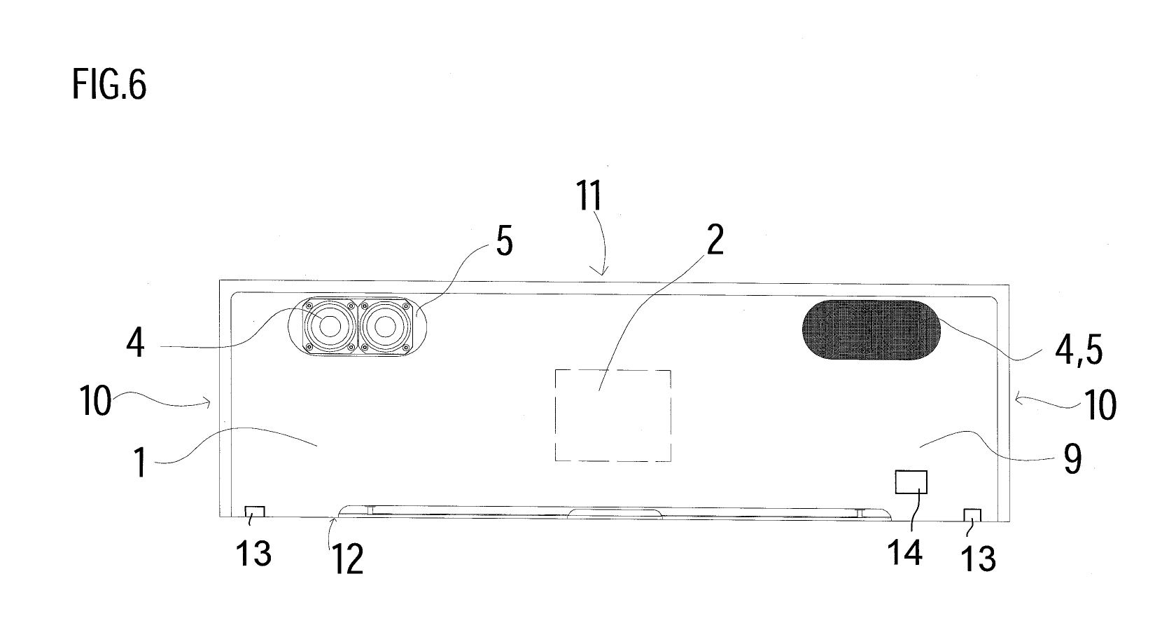

Referring now, particularly to FIG. 1, there is shown a shelf or shelf device according to the present invention substantially comprising a shelf base body 1, an audio amplifier 2, and at least one loudspeaker connected to the amplifier.

The base body 1, which may be a singular one-piece structure or a multi-component assembly, is substantially a rectangular parallelepiped body, preferably of wood or processed wood. Other materials, such as plastic materials, stone or metal, are also conceivable. The shelf thus has a top surface 8, a bottom surface 9, two shorter side surfaces 10 and two longer side surfaces 11, 12. One longer side surface forms the front surface 11 of the shelf, while the other side surface forms the back surface 12 of the shelf in its preferred mounting position.

The shelf is provided with at least one recess for at least one loudspeaker. Preferably, a first pair of recesses 5 is formed in the respective bottom surface 9. A second pair of recesses 6 is arranged in the front surface 11 of the shelf. The first pair of recesses 5 is preferably equipped with bass and/or mid-frequency loudspeakers 4. Alternatively or additionally, a recess for a subwoofer can also be provided (not shown). A bass reflex system can also be integrated in the shelf (not shown). The second pair of recesses 6 is preferably equipped with high-frequency loudspeakers 3. The second pair of recesses 6, or the high-frequency loudspeakers 3, are preferably arranged at both ends of the shelf to create a most advantageous stereo effect. Preferably, the loudspeakers are covered by suitable baffle cloths or grilles. The baffle cloths or grilles can imitate the surface structure of the base body.

Connection hardware 13 for the wall mounting of the shelf can be provided in the back surface 12 of the shelf. They can be, for example, keyhole recesses. The shelf can be directly mounted on a wall. The shelf can also be inserted in a rack.

The audio amplifier 2 is integrated in the shelf. For this purpose, a further recess can be provided, for example closed off by way of a suitable flap (not shown). However, the shelf can also have a multi-part structure, so that the audio amplifier is installed in the interior of the shelf.

Furthermore, the shelf is equipped with at least one interface for further electronic devices. This can be a simple jack plug, but can also be a more complex interface. An MP3 player dock or a so-called “iPod® Dock” 7 is provided, for example, in particular a 30-pin dock for an iPod/iPhone. An iPod® or iPhone® (not shown) connected to the interface serves, for example, as a source for electrical signals, in particular audio signals, that are amplified by means of the amplifier and output by the loudspeakers. Preferably, the interface is configured in such a manner that the iPod® or the iPhone® are both held upright by the interface. The above-mentioned interface can also implement a battery charging function for the iPod/iPhone.

Furthermore, alternatively or additionally, a USB interface (not shown) can be provided, for example, as a connection means for other MP3 players, smart phones and/or computers. The above-mentioned interface can also be used to implement a battery charging function for the connected devices.

Also, alternatively or additionally, an AUX connection interface can be provided for audio playback from external devices.

Furthermore, alternatively or additionally, an interface for video output to TV sets or computers can be provided via a video connection (for example component video (Y, Pb and Pr)).

The interface can be basically adapted to any requirements for connecting so-called multimedia devices.

The shelf according to the present invention is further equipped with a power connection and/or a power supply 14, illustrated here as a diagrammatic box.

The power connection can be arranged, for example, on the rear face of the shelf. The power supply can be implemented as an accumulator, for example, or it may comprise a battery box.

1. A shelf, comprising:
a shelf base body; and
an audio amplifier and at least one loudspeaker connected to said audio amplifier mounted to said shelf base body.

2. The shelf according to claim 1, wherein said shelf base body has a shape of a rectangular parallelepiped.

3. The shelf according to claim 1, wherein said shelf base body is formed with a top surface, a bottom surface, two relatively shorter side surfaces and two relatively longer side surfaces, and wherein said longer side surfaces respectively form a front surface of the shelf and a rear surface of the shelf in a preferred mounting position thereof.

4. The shelf according to claim 1, wherein said shelf base body is formed with at least one recess for accommodating said at least one loudspeaker.

5. The shelf according to claim 1, wherein said shelf base body has a bottom surface, in a preferred mounting position thereof, with at least one first pair of recesses formed in said bottom surface, and bass and/or mid-frequency loudspeakers disposed in said first pair of recesses.

6. The shelf according to claim 5, wherein said shelf base body has a front surface, in the preferred mounting position thereof, with at least one second pair of recesses formed in said front surface and high-frequency loudspeakers mounted in said second pair of recesses.

7. The shelf according to claim 1, wherein said shelf base body has a front surface, in a preferred mounting position thereof, with at least one pair of recesses formed therein and a pair of said loudspeakers mounted in said pair of recesses.

8. The shelf according to claim 1, which comprises connection hardware for facilitating wall-mounting of the shelf.

9. The shelf according to claim 1, which comprises at least one interface for electronic devices mounted to said shelf base body.

10. The shelf according to claim 9, wherein said at least one interface is configured for connecting one or more multimedia devices.

11. The shelf according to claim 9, wherein said at least one interface is configured for connecting one or more audio devices.

12. The shelf according to claim 1, wherein said at least one interface is selected from the group consisting of an iPod® Dock, a USB interface, an AUX connection, and a video connection.

13. The shelf according to claim 1, which comprises a power connection and/or a power supply mounted to said shelf base body.

14. A shelf, comprising:
a shelf base body formed with a plurality of voids and electronic devices, including an audio amplifier and at least one loudspeaker, integrated in said shelf base body and disposed in said voids to form an unitary structure therewith; and
an interface for an audio player, said interface being connected to said audio amplifier and configured to receive signals from the audio player to be amplified in said audio amplifier and played over said at least one loudspeaker.

15. The shelf according to claim 14, wherein said interface device is a docking connector for an of an iPod® or iPhone®, a dock for an MP3 player, a USB interface, an AUX connection, or a video connection.
